(19) United States
(12) Patent Application Publication
(10) Pub. No.: US 2025/0003901 A1
(43) Pub. Date: Jan. 2, 2025

(54) METHOD FOR DETECTING ICING USING A THERMOELECTRIC SENSOR

(71) Applicant: "MICROLAB" LIMITED LIABILITY COMPANY, Moscow (RU)

(72) Inventors: Gennady Gyusamovich GROMOV, Moscow (RU); Semen Aleksandrovich GLYAZER, Moscow (RU)

(21) Appl. No.: 18/707,067

(22) PCT Filed: Nov. 21, 2022
(86) PCT No.: PCT/RU2022/050369

§ 371 Date: May 2, 2024

(30) Foreign Application Priority Data
Dec. 16, 2021 (RU) 2021137255

(51) Int. Cl. G01N 25/04

(52) U.S. Cl. CPC G01N 25/04

(57) ABSTRACT

The invention relates to the field of temperature measurement and heat measurement and can be used for the remote detection of icing. A method for determining the phase transition temperature and volume of a sample of liquid includes determining and stabilizing the starting temperature of a contact surface, and subsequently cooling said surface at a constant rate while taking readings from a temperature sensor and a heat flux sensor. The transition phase temperature in the cooling step is determined on the basis of an abrupt change in the temperature of the crystallizing sample. The crystallization end point is determined on the basis of a change in the heat flux. The contact surface is then heated to its starting temperature with readings being taken from the temperature sensor and the heat flux sensor, and the phase transition temperature in the step of heating the crystallized sample is determined on the basis of a change in the slope of the temperature-time curve at the point when the sample stops melting. The mass of the sample is determined on the basis of the heat flux-time curve. The result is more accurate measurement of both the phase transition temperature and the quantitative characteristics of the sample.

### FIELD OF THE INVENTION

A proposed invention relates to the field of temperature measurement and heat measurement and can be used for the remote detection of icing and determination of environmental conditions that are similar to those for the formation or susceptibility to the formation of icing on various surfaces, such as road surfaces, runways, aircraft surfaces, wind turbines, power lines, etc.

### PRIOR ART

Currently, the thermoelectric sensors used to detect icing and the conditions for its probable occurrence are based on capturing the water-ice and ice-water phase transition points, which enables determination or estimation of temperature of icing and the intensity of icing (amount of ice).

Typically, such sensors have a Peltier element, which is used to perform cyclic cooling and heating of the test sample within a temperature range that is near the crystallization temperature.

The phase transition is captured based on a physical pattern when the crystallization or melting, as a phase transition of the first kind, releases a significant amount of heat at a constant temperature.

A measurement method is known from the prior art (D. I. Katz, Frensor: A New Smart Pavement Sensor, Transportation Research Record #1387, pp. 147-150,1993, ISBN 0309054583), wherein the icing sensor consists of a Peltier element and a thermal sensor located under the cooled surface of the Peltier element. In accordance with a known physical pattern, when cooling a water sample, first there is a noticeable overcooling of the liquid (water or aqueous solution) and, only after that, there is a spontaneous phase transition of water from liquid to solid state with the release of a significant amount of heat and with sample temperature rising to the phase transition temperature.

A method to determine the phase transition temperature using such sensor involves capturing sequentially first an abrupt temperature change, once the sample is overcooled (first point), and then a maximum temperature (second point), which is identified as the crystallization temperature.

However, this method and such apparatus have some disadvantages. First of all, the known method lacks an algorithm for determining the quantitative characteristics of the sample, other than an indirect one, based on the crystallization phase duration.

Moreover, if the crystallization temperature is determined using this method, then the true crystallization temperature may differ markedly from the one obtained by measurement. The reason is that, structurally, the temperature sensor is placed near those parts of the structure that, due to overcooling in the first phase, have a temperature substantially below the crystallization temperature. Therefore, the temperature sensor will capture an underestimated temperature in the range between the true phase transition temperature and the overcooled ambient temperature. For this reason, obtaining a reliable crystallization temperature requires making empirical adjustments in order to introduce the necessary corrections. However, this reduces the reliability and accuracy of determining the phase transition temperature.

A thermoelectric icing sensor is also known from the prior art (see RU2534493, Cl. B64D15/20, published on Nov. 27, 2014). A known thermoelectric icing sensor comprises a thermoelectric module made in the form of a Peltier element acting as a heat pump and a temperature sensor mounted on the external sensing surface.

Based on a pre-defined algorithm and depending on the ambient temperature and its proximity to the crystallization temperature, the Peltier element heats up or cools down the sensing surface. The temperature changes are tracked by the temperature sensor. If there are conditions for ice formation on the surface, the temperature of the sensing surface becomes stable for the period of water-ice phase transition, with the release of latent heat by the ice formation. The thermoelectric sensor captures the specified phase transition temperature, thereby identifying the occurrence of ice formation, and the quantitative characteristics of ice formation are evaluated by measuring the amount of power supply to the heat pump during this period, as this correlates directly with the heat released or absorbed during the phase transition.

In this sensor, the algorithm for identifying the phase transition temperature is similar to the one used in the previously mentioned method and is based on the phase transition temperature which becomes stable for a time. In other words, the accuracy of this method for identifying the phase transition temperature is also low.

The disadvantage of this method for determination of the amount of ice is the inaccuracy of such determination since, in essence, the quantitative characteristics of ice formation are determined indirectly by the power consumption of the Peltier module. The power consumption depends substantially on the operating conditions, namely the ambient temperature, the heat exchange with the environment and the condition of the Peltier module. For this reason, the determination of the quantitative characteristics of the sample is approximate.

The closest analog to the claimed method for determining the phase transition temperature and quantitative characteristics of ice formation is the method for determining the phase transition disclosed in RU 162213, published on Feb. 10, 2021, IPC B64D15/20.

A known thermoelectric icing sensor comprises a thermoelectric module in the form of a Peltier element, a thermoelectric heat flux sensor, the upper part of which forms an external surface sensitive to ice formation and which is equipped with a temperature sensor. A thermoelectric heat flux sensor is placed on the thermoelectric module.

A thermoelectric module designed as a Peltier element ensures cyclic heating-cooling of the external sensing surface of the heat flux sensor within the temperature range of ice formation.

In case of ice or susceptibility to ice formation on the external sensing surface of the upper part, the thermoelectric heat flow sensor captures the release of the latent heat during the ice formation by detecting a signal corresponding to the heat flowing through it, and the temperature sensor captures the phase transition temperature.

The icing sensor also allows to determine the quantitative characteristics of ice formation by capturing the heat that passes through the integrated heat flux sensor over the ice formation period. This amount of heat at the known specific heat of ice formation allows to determine the amount of ice or water (or their layer thickness on the sensing surface).

A disadvantage already noted above is the inaccuracy in determining the phase transition temperature.

There are also some disadvantages in the method for determining the quantitative characteristics of ice formation. This is due to the fact that these icing sensors are designed for wide temperature ranges of operation, including ambient temperatures above and below zero (° C.). Amid fluctuating conditions, the heat exchange between the operating sensor and the environment varies over a wide range. Therefore, the heat flux captured by the heat flux sensor is significantly affected by external factors. This means that the quantitative estimates obtained using such method are very approximate.

The technical problem to be solved by the claimed invention is the development of a reliable and simple method for determining the phase transition of a liquid and estimating its quantitative characteristics using a thermoelectric icing sensor.

The technical result of the proposed invention is to improve the accuracy of measurements, including both the phase transition temperature and the quantitative characteristics of the sample.

The technical problem is solved and the technical result is achieved by the fact that the method for determining the phase transition temperature and volume of a liquid sample using a thermoelectric icing sensor, which comprises a thermoelectric module, a temperature sensor and a thermoelectric heat flux sensor provided with a contact surface in contact with a sample, includes the steps at which:
a starting temperature TO of the contact surface is set and stabilized by adjusting the thermoelectric module;
the contact surface is cooled at a constant rate by adjusting the thermoelectric module while reading the temperature sensor and heat flux sensor;
the phase transition temperature during the cooling phase is determined by the abrupt temperature spike in the crystallizing sample;
the time when the crystallization ends is determined by the change in the heat flux;
the heating of the contact surface to temperature TO is started by means of the thermoelectric module while reading the temperature sensor and heat flux sensor;
the phase transition temperature at the step of heating the crystallized sample is determined by the change in the slope of temperature dependence on time at the moment when the sample melting is completed;
the sample weight is determined using the dependence of the heat flux on time, as obtained from the heat flux sensor.

Preferably, the sample weight is determined by the following formula

$$m = \frac{1}{{Q}_{K}} Δ t {\sum }_{1}^{n} ( {q}_{i} - {q}_{0} ) \qquad ( 1 )$$

where ‘m’ is the weight of water (ice) in the sample; ‘Q_{K}’ is the specific heat of crystallization; ‘Δt’ is the time step of heat flux measurement; ‘q₀’ is the heat flux at the beginning of the cooling phase of the measurement cycle; ‘qi’ is the heat flux at the i-th step of measurement from the beginning of crystallization (i=1 is the beginning of crystallization), ‘n’ is the last step of water crystallization measurement. The use of heat flux data enables the most accurate determination of the true phase transition temperature, and hence improves the accuracy of determining the quantitative characteristics of the sample (liquid/ice).

Preferably, the starting temperature TO is deliberately selected above the crystallization temperature of the sample. The selection of the starting temperature is based on the fact that such temperature allows to deliberately melt the sample in the form of ice if, initially, this was already the ice (for example, at low ambient temperature), which improves the accuracy of measuring both the phase transition temperature and quantitative characteristics of the sample.

Preferably, the temperature sensor and the heat flux sensor are read at equal time intervals, which enables to avoid missing the moment of change in the temperature and heat flux, and, therefore, to improve the accuracy of determining the phase transition temperature and quantitative characteristics of the sample.

### BRIEF DESCRIPTION OF THE DRAWINGS

FIG. 1 shows the chart of characteristic changes in temperature (T) and heat flux (Flow) in the operating icing sensor when there is water in the cuvette. It marks the points for determining the phase transition temperature at the cooling step (Tf1) and at the heating step (Tf2). The integral under the heat flow curve represents the total heat of crystallization (Qf). TO is the starting temperature of the contact surface at the beginning of the cooling phase.

FIG. 2 shows a chart illustrating an embodiment of the proposed method at initial ambient temperature Ta=O° C. and water sample volume of 5 μl. It shows the change in temperature (Ti) and heat flux (qi) at time step (i). The following characteristic points are marked on the chart: ‘i=0’ is the beginning of the experiment starting from ambient temperature T=Ta; ‘i=n1’ is the stabilization of the starting temperature Tn0=T0, the beginning of the cooling phase; ‘i=n2’ is the limit overcooling of the water sample to Tn1; ‘i=n3’ is the point of the local maximum temperature Tn2; ‘i=n3’ is the end of crystallization, the beginning of the heating phase; ‘i=n4’ is the end point of melting in the ice sample Tn4.

FIG. 3 shows the chart demonstrating the correlation of the results obtained in determining the sample volume by the claimed method with a known (specified, actual) sample volume. The measurements were taken at three temperatures.

FIG. 4 shows the dependence of the change in the phase transition temperature on the sample volume at three different temperatures (+15° C., 0° C., −15° C.). The value is measured in the cooling phase Tf1 (a) and heating phase Tf2 (b).

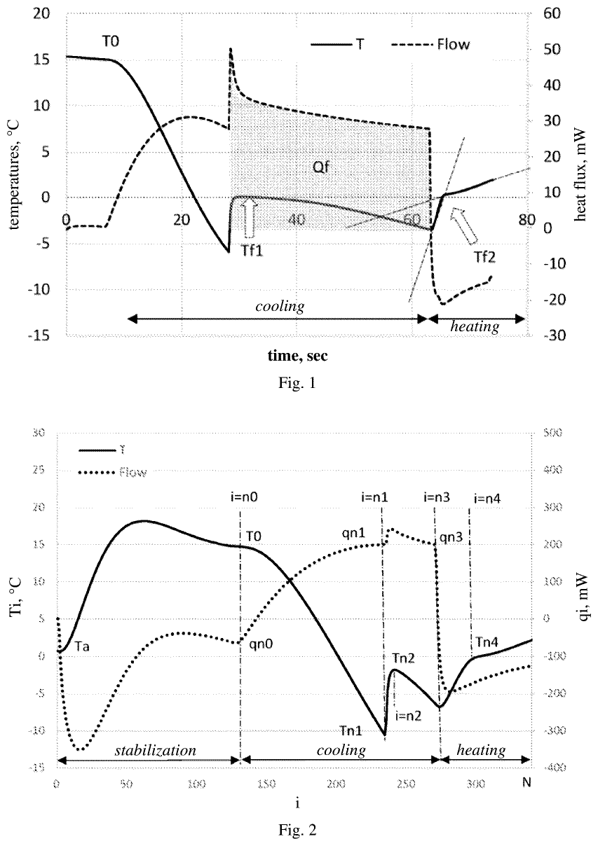

### AN EMBODIMENT OF THE INVENTION

The proposed method for determining the phase transition temperature and the amount of sample is implemented using thermoelectric icing sensor as follows.

Regardless of the external temperature conditions (starting temperature Ta), the temperature of the sensing surface at the beginning of the cycle is brought to a fixed value of TO, which is known to be higher than the crystallization temperature of the liquid, e.g. +15° C., by adjusting the thermoelectric module. Then the temperature TO is stabilized for a short time. This preparation of the sensor allows to melt the sample, if the sample was initially in the form of ice, e.g., at low ambient temperatures. In this case, the readings of the ‘Ti’ temperature sensor and ‘qi’ heat flux sensor are captured at equal time intervals of Δt.

Once the temperature has stabilized at TO, the thermoelectric module is used to start the process of gradual temperature reduction. The sample on the sensor surface is cooled down and spontaneous crystallization occurs when the liquid reaches the limit temperature of overcooling. In this case, the limit temperature of liquid cooling is not known in advance, because the sample volume is unknown, but it has a value below 0° C. This moment is detected by an abrupt upward change in the temperature value. The heat flux values also increase which is related to the release of crystallization heat (see FIG. 1).

If there is no sample on the sensing surface, this temperature will be reached without phase transition events and the measurement ends.

Next, the temperature increases and reaches a local maximum, at which the temperature sensor is read, and it corresponds to the value of Tn2. The value of this temperature is near the true crystallization phase transition temperature (Tf), but lower than it due to the impact of ambient factors. This is the measured crystallization temperature in the cooling phase Tn2=Tf1. The temperature after the beginning of crystallization, which is determined at the maximum spike point, is used as an estimate of the phase transition temperature during crystallization. The temperature measured in this way will always be underestimated.

The sample of liquid on the sensing surface continues to crystallize for some time. The duration of crystallization process depends on the sample volume. The temperature and heat flux values are gradually decreasing.

At the end of crystallization, which is monitored by detecting the drop of the signal from the heat flux sensor to the value that was just before the beginning of crystallization, the thermoelectric module is switched on to heating in order to reach the initially specified temperature, from which the cycle began.

The maximum true phase transition temperature is determined at the second phase of the cycle during the heating. When the ice melts, there is no mirror (relative to overcooling) overheating of the ice. The ice begins to melt gradually without a temperature spike. As a result, no plateau is formed on the temperature curve and there is no marked response of the heat flux sensor.

However, once the melting is complete, the temperature curve experiences a characteristic fracture caused by an abrupt change in the heating rate after the ice sample ceases to absorb the heat released by the melting.

The temperature of the ice-liquid phase transition measured in this way is quantitatively more reliable and correlates with the true temperature of the sample, since there is virtually no parasitic non-equilibrium impact on the temperature sensor as all elements are heated simultaneously.

Once the measurement cycle is completed, the obtained data is processed as follows:

1. Calculation of the crystallization heat of the sample, sample weight and sample volume.

The array of the heat flux values within the interval qi=qn1 to qi=qn3 (i=n1 to i==n3) is used to find the total amount of crystallization heat of the sample as follows

$$Q = {\sum }_{n 1}^{n 3} [ \frac{( {q}_{i} + {q}_{i + 1} )}{2} - {q}_{n 0} ] Δ t \qquad ( 2 )$$

The weight of the water sample ‘m’ or the sample volume ‘Ve’ is calculated as follows.

$$m = \frac{Q}{{Q}_{k}} \qquad ( 3 )$$

$${V}_{E} = \frac{Q}{{Q}_{k}} \times \frac{1}{ρ} \qquad ( 4 )$$

The water density is ρ=1 g/mL. Latent heat of water crystallization Q_{K}=330 J/g.

2. Determination of the phase transition temperature in the heating phase.

The array of measured temperature values is extracted from the beginning of the heating phase (i=n3) and up to the end of the experiment (i=N) as follows:

$${T}_{i = n 3} … \cdot {T}_{i = N} \qquad ( 5 )$$

The third derivative of the temperature change over time is found. The time interval i=n4, when the third derivative of the temperature over time passes from the negative area to the positive area, is determined.

$$\frac{\partial T}{{\partial }^{3} t} \geq 0 \qquad ( 6 )$$

This corresponds to the inflection point on the temperature curve shown in FIG. 1. The temperature value for this interval Tn4 is memorized. This is the measured value of the phase transition temperature for ice sample melting during the heating phase Tn4=Tf2.

The amount of ice, water is determined by the measurement result of the heat flux sensor. Namely, this involves using the integral of the heat flux over the ice crystallization period. At the same time, an adjustment is made for the initial heat flux at the temperature TO.

The calculation formula is provided below

$$m = \frac{1}{{Q}_{K}} Δ t {\sum }_{1}^{n} ( {q}_{i} - {q}_{0} ) \qquad ( 1 )$$

where ‘m’ is the weight of water (ice) in the sample; ‘Q_{K}’ is the specific heat of crystallization; ‘Δt’ is the time step of heat flux measurement; ‘q₀’ is the heat flux at the beginning of the cooling phase of the measurement cycle; ‘qi’ is the heat flux at the i-th step of measurement from the beginning of crystallization (i=1 is the beginning of crystallization), ‘n’ is the last step of water crystallization measurement.

### SPECIFIC EMBODIMENTS

A thermoelectric icing sensor was made in accordance with the description provided in RU1620213, and comprised a thermoelectric module connected to the lower part of the thermoelectric heat flux sensor, the opposite upper part of which formed an external surface sensitive to ice formation and was equipped with a temperature sensor.

The measurements were taken at three different ambient temperatures: +15° C., 0° C., and 15° C. At each temperature, the measurements were taken with a different amount of sample volume set precisely within the range of 0-100 μl. For comparison, the temperature was determined in the cooling phase and in the heating phase.

An accurately measured water sample of v=10 μl was placed on a surface sensing the ice formation. The ambient temperature Ta was 0° C.

To implement the preliminary stabilization phase, the thermoelectric module in the heating phase produced a starting temperature of the sample (TO) equal to +15° C. and maintained such temperature for a short period of time. The temperature of the sample was measured by a temperature sensor. The readings of the ‘Ti’ temperature sensor and ‘qi’ heat flux sensor were captured at equal time intervals of Δt=0.15 seconds.

Where ‘Ti’, ‘qi’ is the reading of the heat flux temperature, respectively, at the i-th time interval (i=0 . . . N, where ‘0’ is the start of measurements, and ‘N’ is the end of measurements).

Thus, an array of data on ‘Ti’ and ‘qi’ is accumulated at i=0 . . . N.

Once the temperature was stabilized at T0=+15° C., a gradual decrease in temperature was set by controlling the thermoelectric module.

In this case, the value of the reading from the heat flux sensor, before the temperature started to decrease, was qn0, while the respective number of the time interval i=n0.

The spontaneous crystallization occurs when the limit temperature of overcooling the liquid, which is not known in advance (and is noticeably below +0° C.), is reached. This moment is detected by observing an abrupt upward change in temperature. The temperature value Tn1 at number i=n1 corresponds to the overcooling temperature Tc. Therefore, Tn1=Tc.

The readings of the heat flux sensor also show a change (increase) in the signal related to the release of crystallization heat. The value of the heat flux before this change is memorized separately as ‘qn1’ in time interval i=n1.

The temperature increases and reaches a local maximum, which corresponds to Tn2 (i=n2). The temperature Tn2 is near the true crystallization phase transition temperature (Tf), but lower than it due to the impact of environmental factors. This is the measured crystallization temperature in the cooling phase Tn2=Tf1.

The crystallization of the water sample in the cuvette continues for some time, and a gradual decrease in the measured temperature ‘Ti’ and heat flux ‘qi’ is observed.

A moment (i=n3) when the heat flux value is equal to or less than the heat flux value at the point i=n1, i.e. qn3<qn1, is tracked using the heat flux sensor.

All values of the heat flux sensor readings qi=qn1 . . . i=n3 are memorized over the entire time interval i=n1 . . . i=n3. qi=qn3.

From the moment of i=n3+1, the heating phase is started and the temperature is increased using the thermoelectric module until the initial value of the measurement cycle temperature T0=+15° C. is reached.

In the entire time interval of i=n3+1, the temperature values of Ti=T(n3+1) . . . Ti=T(n=N) are memorized until the end of i=N measurements.

Once the measurement cycle (i=N) is completed, the measured and memorized data is processed as follows:

1. The sample crystallization heat, sample weight and sample volume are calculated according to formulas (1)-(3).

The value of the latent heat of water crystallization Q_{K}=330 J/g, water density ρ=1 g/mL.

2. The temperature of the phase transition in the heating phase is determined.

The array of measured temperature values is extracted from the beginning of the heating phase (i=n3) and up to the end of the experiment (i=N) in accordance with the expression (5):

The third derivative of the temperature change over time is found in accordance with the expression (6). The time interval i=n4, when the third derivative of the temperature over time passes from the negative area to the positive area, is determined.

This corresponds to the inflection point on the temperature curve shown in FIG. 1. The temperature value for this interval Tn4 is memorized. This is the measured value of the phase transition temperature for ice sample melting during the heating phase Tn4=Tf2.

All measurements are shown in Table 1.

TABLE 1
Measurement results

| | | | | | | |
|---|---|---|---|---|---|---|
| Sample | | | | | | |
| size, μl | Tc, ° C. | Tf1, ° C. | Tf2, ° C. | Q, mJ | m, mg | Ve, μl |

T0 = +15° C.

| | | | | | | |
|---|---|---|---|---|---|---|
| 5 | −13.35 | −5.89 | −0.12 | 3,800 | 11.5 | 11.5 |
| 10 | −10.79 | −2.63 | −0.15 | 5,360 | 16.2 | 16.2 |
| 20 | −8.05 | −1.58 | −0.21 | 8,813 | 26.7 | 26.7 |
| 30 | −5.65 | −1.16 | −0.26 | 10,859 | 32.9 | 32.9 |
| 40 | −6.17 | −0.86 | −0.30 | 15,227 | 46.1 | 46.1 |
| 50 | −5.92 | −0.79 | −0.37 | 19,649 | 59.5 | 59.5 |
| 60 | −5.60 | −0.77 | −0.38 | 22,243 | 67.4 | 67.4 |
| 75 | −5.60 | −0.71 | −0.43 | 25,543 | 77.4 | 77.4 |
| 100 | −5.60 | −0.75 | −0.48 | 32,143 | 97.4 | 97.4 |

T0 = +0° C.

| | | | | | | |
|---|---|---|---|---|---|---|
| 5 | −14.67 | −6.60 | −0.23 | 1,475 | 4.5 | 4.5 |
| 10 | −10.58 | −3.24 | −0.11 | 3,788 | 11.5 | 11.5 |
| 20 | −9.07 | −1.67 | −0.27 | 5,993 | 18.2 | 18.2 |
| 30 | −7.20 | −1.43 | −0.24 | 8,352 | 25.3 | 25.3 |
| 40 | −5.09 | −1.23 | −0.19 | 10715 | 32.5 | 32.5 |
| 50 | −7.86 | −1.31 | −0.37 | 15,553 | 47.1 | 47.1 |
| 60 | −7.54 | −1.31 | −0.38 | 18,457 | 55.9 | 55.9 |
| 75 | −7.39 | −1.29 | −0.43 | 22,173 | 67.2 | 67.2 |
| 100 | −6.66 | −1.26 | −0.39 | 35,072 | 106.3 | 106.3 |

T0 = −15° C.

| | | | | | | |
|---|---|---|---|---|---|---|
| 5 | −16.66 | −8.46 | −0.17 | 2,531 | 7.7 | 7.7 |
| 10 | −10.48 | −3.11 | −0.19 | 4,722 | 14.3 | 14.3 |
| 20 | −10.33 | −2.12 | −0.24 | 5,749 | 17.4 | 17.4 |
| 30 | −8.12 | −1.89 | −0.30 | 11,022 | 33.4 | 33.4 |
| 40 | −7.90 | −1.76 | −0.36 | 12,530 | 38.0 | 38.0 |
| 50 | −6.40 | −1.68 | −0.42 | 17,447 | 52.9 | 52.9 |
| 60 | −6.91 | −1.67 | −0.54 | 23,354 | 70.8 | 70.8 |
| 75 | −6.52 | −1.65 | −0.59 | 27,882 | 84.5 | 84.5 |
| 100 | −5.42 | −1.59 | −0.60 | 35,092 | 106.3 | 106.3 |

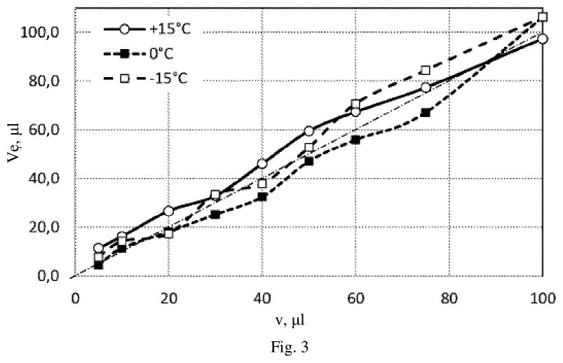

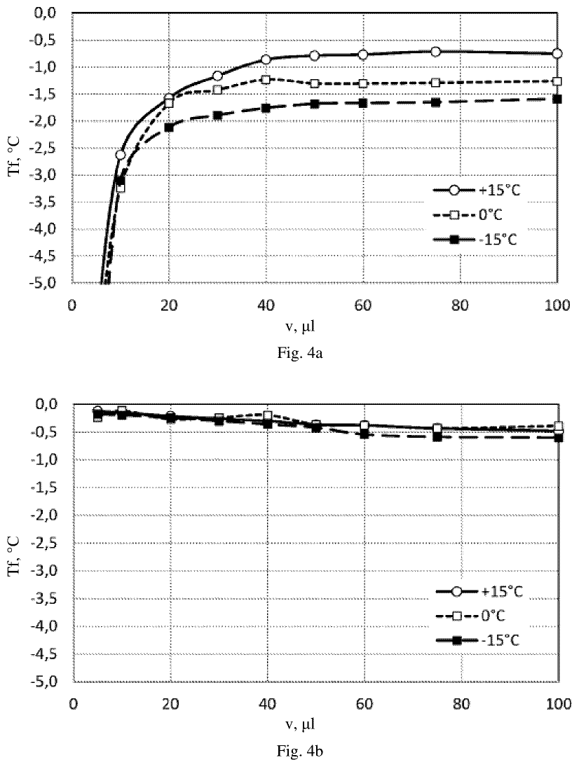

The obtained results (Table 1) allow to demonstrate graphically the found dependencies, such as the one of the measured sample values ‘Ve’ at different temperatures ‘Ta’ and given sample volumes ‘v’ (see FIG. 3), and the dependence of measured crystallization temperature in the cooling phase Tf1 (FIG. 4a) and the dependence of measured melting temperature of the ice sample in the heating phase Tf2 (FIG. 4b) on the starting temperature and sample size Ta.

FIG. 3 shows that the icing sensor determines, with good accuracy, the volume of water in the sample at different temperatures.

The comparison with the specified values of the sample size demonstrates a high convergence of the measurement results.

FIG. 4 shows that the temperature of the water-ice phase transition can be determined at both steps of the cycle, including the cooling step and the heating step. However, at the cooling step, the obtained numerical values deviate markedly from the true value of the crystallization temperature. Moreover, this deviation increases when the sample size is reduced to the minimum. Also, the deviation becomes greater as the ambient temperature drops.

At the same time, the phase transition temperature determined at the heating step has a smaller deviation from the true value (Tf) and, with the change of sample volume and at different ambient temperatures, this deviation remains insignificant (less than 1° C.). This meets the practical requirements for today's icing sensors.

Therefore, the proposed method for determining the phase transition temperature and volume of the liquid sample using a thermoelectric icing sensor:
ensures capturing phase transition events, i.e. detecting ice or susceptibility to ice formation even at the early stages. Moreover, the sensitivity of this method is assured through duplicated detection based on the readings of the temperature sensor and the heat flux sensor.
ensures reliable determination of the phase transition temperature, which is performed twice per measurement cycle. This is provided with an error of estimate during the cooling step and precisely during the heating step.
ensures, with high accuracy, the quantitative determination of the sample size based on the readings of the heat flux sensor and the processing of results using the proposed method.

This method for determining the phase transition temperature and the amount of sample using a thermoelectric icing sensor, according to the proposed invention, may be widely implemented across the industrial sector, namely in the field of temperature measurement and heat measurement using thermoelectric icing sensors.

1. A method for determining the phase transition temperature and volume of a sample of liquid using a thermoelectric icing sensor comprising a thermoelectric module, a temperature sensor and a thermoelectric heat flux sensor provided with a contact surface in contact with the sample, which includes the steps at which:
a starting temperature TO of the contact surface is set and stabilized by adjusting the thermoelectric module;
the contact surface is cooled at a constant rate by adjusting the thermoelectric module while reading the temperature sensor and heat flux sensor;
the phase transition temperature during the cooling phase is determined by the abrupt temperature spike in the crystallizing sample;
the time when the crystallization ends is determined by the change in the heat flux;
heating of the contact surface to temperature TO is started by means of the thermoelectric module while reading the temperature sensor and heat flux sensor;
the phase transition temperature at the step of heating the crystallized sample is determined by the change in the slope of temperature dependence on time at the moment when the sample melting is completed;
the sample weight is determined using the dependence of the heat flux on time, as obtained from the heat flux sensor;
the volume of a sample of the liquid is determined based on the measured amount of crystallization heat of the sample, specific heat of crystallization of the sample and density of the liquid sample.

2. A method according to claim 1 wherein the sample weight is determined by the following formula
$$m = \frac{1}{{Q}_{K}} Δ t {\sum }_{1}^{n} ( {q}_{i} - {q}_{0} )$$
where ‘m’ is the weight of water (ice) in the sample; ‘Q_{K}’ is the specific heat of crystallization; ‘Δt’ is the time step of heat flux measurement; ‘q₀’ is the heat flux at the beginning of the cooling phase of the measurement cycle; ‘qi’ is the heat flux at the i-th step of measurement from the beginning of crystallization (i=1 is the beginning of crystallization), ‘n’ is the last step of water crystallization measurement.

3. A method according to claim 1 wherein the starting temperature TO is deliberately selected above the crystallization temperature of the sample.

4. A method according to claim 1 wherein the sample volume is determined by the following formula
$${V}_{E} = \frac{Q}{{Q}_{k}} \times \frac{1}{ρ}$$
where ‘p’ is the water density at ρ=1 g/ml, Q_{K} (J/g) is the specific crystallization heat of the sample, and Q (J) is the total amount of crystallization heat of the sample.

5. A method according to claim 1 wherein the temperature sensor and the heat flux sensor are read at equal time intervals.
